(19) United States
(12) Patent Application Publication
(10) Pub. No.: US 2025/0005248 A1
(43) Pub. Date: Jan. 2, 2025

(54) INTERPOSER STITCH THROUGH A TOP CHIPLET

(71) Applicant: XILINX, INC., San Jose, CA (US)

(72) Inventor: Martin L. VOOGEL, Niwot, CO (US)

(21) Appl. No.: 18/217,339

(22) Filed: Jun. 30, 2023

(51) Int. Cl. G06F 30/392

(52) U.S. Cl. CPC G06F 30/392

(57) ABSTRACT

Embodiments herein describe devices that include an interposer with a stitch formed from overlapping exposure areas, which may result in the interposer having a total surface area that is greater than a maximum reticle field corresponding to the exposure areas. Two or more integrated circuits (e.g., chiplets) can be disposed on the interposer. At least one of the integrated circuits is disposed over the stitch. The interposer can provide chip-to-chip connections between the integrated circuits.

### TECHNICAL FIELD

Examples of the present disclosure generally relate to connecting a chiplet to an interposer where the chiplet covers a stitch in the interposer.

### BACKGROUND

Many devices include multiple integrated circuits (or dies, chips, or chiplets) that are interconnected on a substrate or interposer. That is, chip-to-chip connections can be used to form devices that are 1×2, 1×3, 1×4, etc. To facilitate multiple integrated circuits (ICs) on the same interposer, the interposer can include one or more stitches. A stitch is a region where different exposure areas overlap, permitting the interposer to have an area that exceeds a maximum reticle size. That is, stitches enable the interposer to be larger than a reticle size so that multiple ICs (which are also constrained by the reticle size) can be disposed on a same interposer. These stitches are arranged between ICs. For example, if two ICs are disposed on the same interposer in a 1×2 arrangement, the ICs are positioned on the interposer so that the stitch extends between the ICs.

### SUMMARY

One embodiment described herein is a device that includes an interposer with a stitch formed from overlapping exposure areas and two or more integrated circuits (ICs) disposed on the interposer where a first IC of the two or more ICs is disposed over the stitch, and where the two or more ICs are connected via the interposer.

One embodiment described herein is a method that includes forming an interposer with stitch using overlapping exposure areas and disposing two or more ICs on the interposer where a first IC of the two or more ICs is disposed over the stitch, and where the two or more ICs are connected via the interposer

One embodiment described herein is a device that includes an interposer with a stitch formed from overlapping exposure areas, a first IC disposed on the interposer where the first IC is disposed over the stitch, and a second IC disposed on the interposer and is not disposed over the stitch where the first and second ICs are connected using chip-to-chip connections in the interposer.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates an IC disposed over a stitch in an interposer, according to an example.

FIG. 2 is a flowchart for forming an interposer with a stitch, according to an example.

FIG. 3 illustrates an interposer with a stitch formed from two exposure areas, according to an example.

FIG. 4 illustrates a design of an IC to support being disposed over a stitch in an interposer, according to an example.

FIG. 5 illustrates a design of an IC to support being disposed over a stitch in an interposer, according to an example.

FIG. 6 illustrates disposing multiple ICs over a stitch in an interposer, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe disposing a chiplet (e.g., an IC) over a stitch in an interposer, rather than in previous solutions where a stitch is positioned between two ICs. Using stitches enables the interposer to be larger than a reticle size so that multiple dies (which are also constrained by the reticle size) can be disposed on a same interposer. To form a stitch, two exposure areas (which are at or below the reticle size and slightly overlap) can be used to fabricate the interposer.

It may be impossible or impractical to align the ICs on the interposer such that the stitch is between the two ICs, which is typically desirable since the stitch is a keep-out region that affects the design of the IC. For example, the number or size of the ICs disposed on the interposer may prevent the stitch from being aligned at a boundary between the ICs. In one embodiment, the stitch is aligned with a keep-out region on the IC which does not include micro bumps, copper pillars, or redistribution layers (RDLs). In yet another embodiment, the stitch is aligned with a region of the IC that does not has fewer (or no) power bumps or boundary between two different power domains in the IC. At these power domain boundaries, the IC does not typically have bumps and RDLs, which means extending the stitch through the IC has less of an impact (or no impact) on the design of the IC.

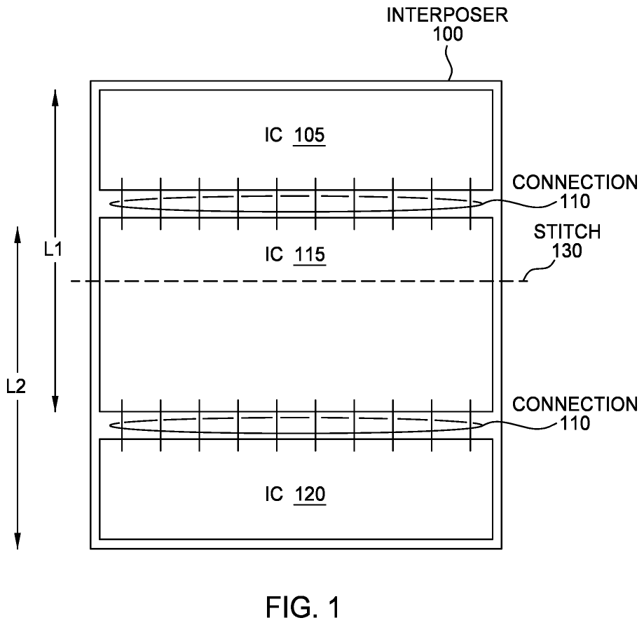

FIG. 1 illustrates an IC 115 disposed over a stitch 130 in an interposer 100, according to an example. In this top view, the ICs 105, 115, and 120 are disposed along a length of the interposer 100. The interposer 100 provides chip-to-chip connections 110 between neighboring ICs, i.e., between IC 105 and IC 115, and between 115 and IC 120. For example, the interposer 100 can be a silicon interposer that includes one or more layers that include traces for forming the connections 110. In one embodiment, the ICs 105, 115, and 120 may be mounted onto the interposer 100 using, e.g., copper pillars, which then electrically couple the ICs 105, 115, and 120 to the connections 110 that route electrical signals from one IC to a neighboring IC.

In this embodiment, the interposer 100 has a surface area that exceeds a reticle limit of the fabrication techniques used to fabricate the interposer. The size of an IC is limited by the reticle limit which defines the amount of area that can be exposed and processed using masks. Currently, for a monolithic die, the maximum size is limited to 33-26 mm which is the reticle limit. Thus, the widths and heights of the ICs 105, 115, and 120 are limited to this reticle limit.

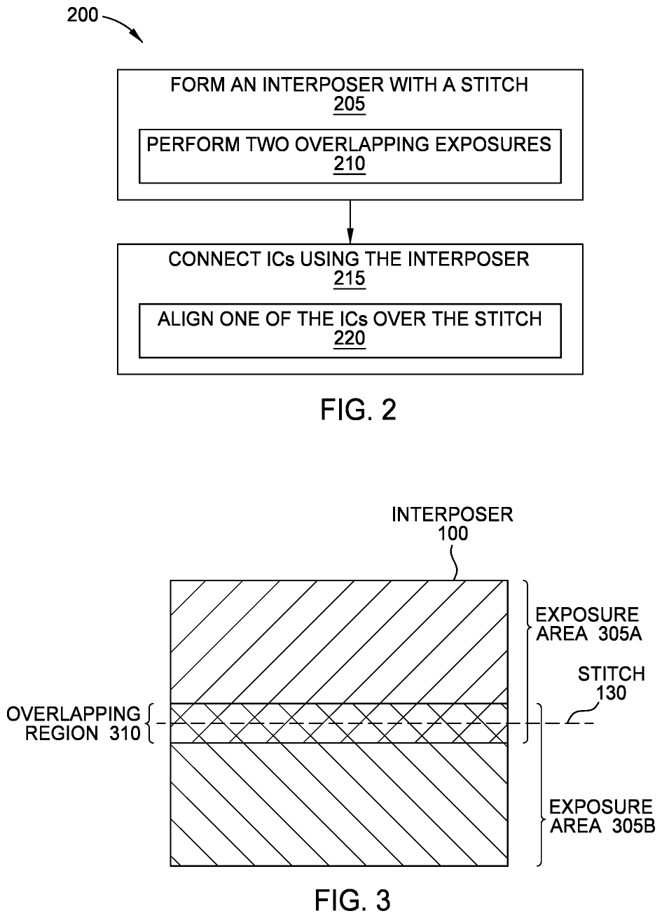

In order for the interposer 100 to support multiple ICs 105, 115, and 120 which have sizes that are at or just below the reticle limit, it has to have a surface area that exceeds the reticle limit. This means that the interposer 100 cannot be fabricated using a single exposure process. Instead, the interposer 100 includes a stitch 130 where at least two exposure areas slightly overlap. This permits the interposer 100 to still have traces to form the connections 110 and have sufficient surface area to support the 1×3 configuration of the ICs 105, 115, and 120. Fabricating the interposer 100 is discussed in more detail in FIGS. 2 and 3.

In one embodiment, the interposer 100 has a total surface area that is greater than the size of the reticle limit (e.g., the maximum reticle field) and can have an area that is (almost) as large as twice the reticle limit.

As mentioned above, it may be impossible to align the stitch 130 so it is between an interface between one of the ICs (e.g., between the IC 105 and the IC 115 or between the IC 115 and the IC 120). For example, the ICs 105 and 120 may have sizes that are below the reticle limit. For example, the IC 105 and the IC 120 may be high-bandwidth memory (HBM), a programmable fabric (e.g., a field programmable gate array (FRPGA), or the like. The combined length (L1) of the IC 105 and the IC 115 and the combined length (L2) of the IC 115 and the IC 120 may exceed the reticle limit. As such, if the stitch 130 were placed between the IC 105 and 115, the length L2 exceeds the reticle limit, and thus, the interposer 100 would need to have a second stitch in order to accommodate both the ICs 115 and 120. The reverse is also true where if the stitch 130 were placed between the ICs 115 and 120, the length L1 exceeds the reticle limit, and thus, the interposer 100 would need to have a second stitch in order to accommodate the ICs 105 and 115. Instead of having two stitches in the interposer, the embodiments herein align the stitch 130 underneath the IC 115.

In one embodiment, the distance from the stitch 130 to an upper edge of the interposer 100, and the distance from the stitch 130 to a lower edge of the interposer 100 are less than or equal to the reticle limit. In one embodiment, the distance from the stitch 130 to the upper edge may be different than the distance from the stitch 130 to the lower edge. In another embodiment, the distance from the stitch 130 to the upper edge and to the lower edge is that same (i.e., the stitch 130 is a middle line of the interposer 100).

One way to avoid aligning the stitch 130 underneath one of the ICs (or to avoid two stitches), is to shrink one of the ICs. For example, the IC 115 could be shrunk so that the length L1 or the length L2 is below the reticle limit. In that case, only one stitch can used, and that stitch can be aligned at one of the chip-to-chip interfaces. However, shrinking the size of the IC 115 reduces the amount of circuitry that can be placed on the IC 115. For example, reducing the size of the IC 115 may reduce its processor power or memory. Doing so may mean the device in FIG. 1 no longer satisfies a customer's requirements. As such, placing the stitch 130 through the IC 115 can avoid multiple stitches and having to reduce the size of one (or more) of the ICs, which can negatively impact the performance of the device.

FIG. 2 is a flowchart of a method 200 for forming an interposer with a stitch, according to an example. At block 205, an interposer is formed with a stitch. In one embodiment, at block 210, the stitch is formed by performed two overlapping exposures, which is discussed in more detail in FIG. 3.

FIG. 3 illustrates an interposer 100 with a stitch 130 formed from two exposure areas 305, according to an example. That is, FIG. 3 illustrates forming the stitch using an overlapping region 310 between two exposure areas 305A and 305B. In this example, each exposure area 305 has a size that is at or below the reticle limit (e.g., the maximum reticle field). Thus, each of the exposure areas 305 can be made using a separate set of masks.

As shown, a bottom of the exposure area 305A overlaps with a top of the exposure area 305B. This overlap forms the overlapping region 310 where both mask sets affect the physical structure of the interposer 100.

Ensuring the exposure areas 305 slightly overlap provides the ability to form the stitch 130 in the overlapping region 310. Without overlapping the exposure areas 305 (e.g. if the exposure areas touched, but did not overlap), it would be very difficult to pattern the traces into the interposer 100 to from the chip-to-chip connections 110 shown in FIG. 1. This is because of misalignment between two exposures. In one embodiment, the overlap of exposures and the minimum widths and space of features (metal lines) on the interposer 100 near the stitch zones is greater than the maximum misalignment.

While masks sets are expensive, masks for the interposer 100, which are currently formed using a 65 nm fabrication method, are much cheaper than masks sets for the ICs, which are currently formed using 7 nm or 3 nm fabrications methods. As such, it is relatively inexpensive to form an interposer that exceeds the reticle limit. In contrast, it may be impossible to use overlapping exposure areas to form an IC that exceeds the reticle limit using a 7 nm or 3 nm technology. That is, it is much more difficult to stitch together ICs compared to stitching together an interposer.

Returning to the method 200, at block 215, the ICs are connected using the interposer. For example, the interposer may include bond pads to which the ICs are bonded to the interposer. Doing so electrically connects the ICs to the chip-to-chip connections in the interposer (that were created at block 205) that extend between neighboring ICs as shown in FIG. 1.

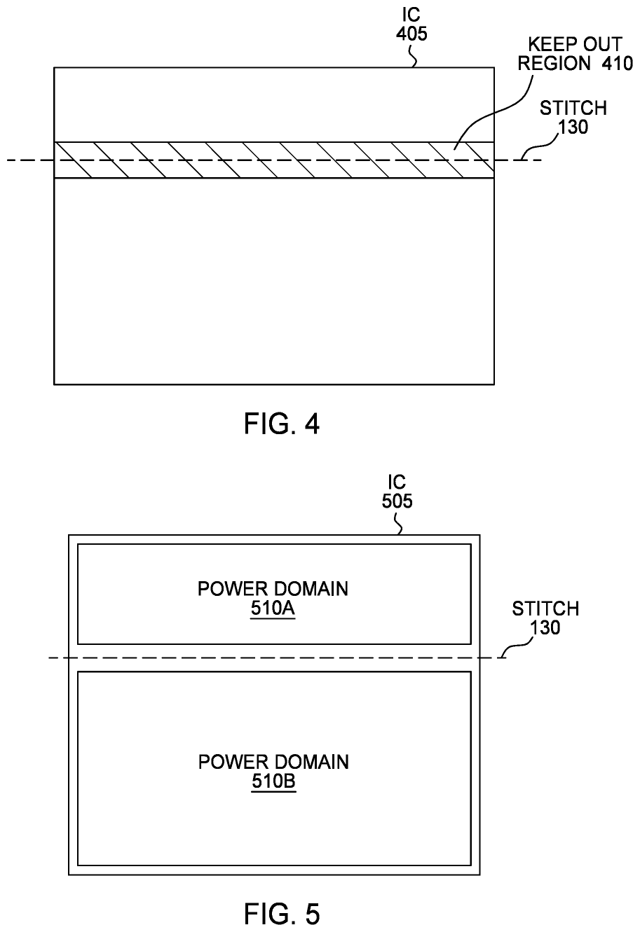

FIG. 4 illustrates a design of an IC 405 to support being disposed over a stitch in an interposer, according to an example. FIG. 4 illustrates that the IC 405 can be designed knowing that it will be disposed over a stitch in an interposer. In this example, the IC 405 includes a keep-out region 410 which excludes certain features of the IC 405 from being placed in this region 410. For example, external micro bumps, copper pillars, and RDLs may not be permitted in the keep-out region 410. In general, the keep-out region 410 may exclude any components in the IC 405 that interface with the interposer, but cannot because of the stitch 130. For instance, because of the keep-out region 410, a circuit designer may unable to make connections from the IC 405 to the interposer in this region 410, but other types of circuitry can be disposed within the keep-out region 410. This may mean the circuit designer has to rely on a different area of the IC 405 to provide certain connections between the IC 405 and the interposer. For example, circuitry in the keep-out region 410 may have to use power connections to the interposer that are outside the keep-out region 410.

FIG. 5 illustrates a design of an IC 505 to support being disposed over a stitch in an interposer, according to an example. Having a keep-out region as shown in FIG. 4 may raise design complications or constraints. For example, if circuitry within the keep-out region is powered using connections to the interposer that are outside of the keep-out region 410, this can cause IR drops and other design problems.

In FIG. 5, the stitch is aligned with a boundary between power domains 510 in the IC, which can mitigate the negative impact of disposing the IC 505 over the stitch 130. The power domains 510 can contain circuitry in the IC that are powered using a different voltage or a different power source. Generally, at the boundary between two power domains, an IC 505 does not include components that would be excluded by a keep-out region (e.g., micro bumps, copper pillars, and RDLs). As such, aligning the stitch 130 to a boundary between power domains 510 can reduce (or remove) the impact the stitch 130 has on the design of the IC 505. Put differently, aligning the stitch 130 at the power domain boundary may not force the circuit designer to make any (or at least fewer) adjustments to the circuit design.

In one embodiment, the power domains 510 include different types of circuitry. For example, the power domain 510A may include programmable fabric (e.g., configurable logic blocks that are interconnected) while the power domain 510B includes digital processing engines (DPEs). For example, the power domain 510B may include an array of DPEs that includes rows and columns. In one embodiment, the DPEs are identical (e.g., homogeneous). That is, each of the DPEs (also referred to as tiles or blocks) may have the same hardware components or circuitry. In other embodiments, the DPEs may be heterogeneous and includes different types of DPEs—digital signal processing engines, cryptographic engines, graphic processing engines, and the like. However, programmable fabric and DPEs are just two examples of different types of circuitry that can be disposed in two different power domains 510 in the same IC 505. Other examples of circuitry that may be disposed in different power domains include memory, processor cores, and the like.

In another embodiment, the stitch aligns with a region of the IC that typically (or naturally) does not have power bumps, or very few power bumps. For example, a boundary between power domains (when the power domains do, or do not, have the same voltage) may not have power bumps. By aligning the stitch with a region with no, or few power bumps, the stitch may have no effect, or a much smaller effect, on the IC circuit design.

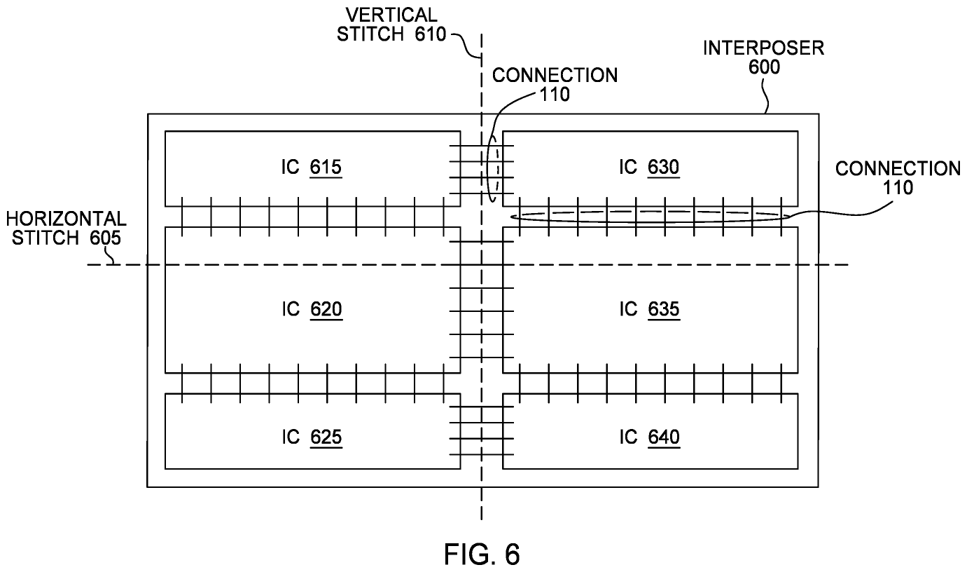

FIG. 6 illustrates disposing multiple ICs over a stitch in an interposer 700, according to an example. FIG. 6 illustrates a 2×3 configuration of ICs on the interposer 700, according to an example. Like above, the interposer 700 provides chip-to-chip connections 110 between neighboring ICs 615, 620, 625, 630, 635, and 640. For example, the interposer 600 can be a silicon interposer that includes one or more layers that include traces for forming the connections 110. In one embodiment, the ICs may be mounted onto the interposer 600 using micro balls or pillars, which then electrically couple the ICs to the connections 110 that route electrical signals from one IC to a neighboring IC.

Unlike 1×2, 1×3, or 1×4 arrangements where at least some of the ICs only use one side to communicate with a neighboring IC, in the 2×3 configuration shown in FIG. 6, each IC 615, 620, 625, 630, 635, and 640 uses two sides to communicate with its two neighboring ICs. For example, IC 615 uses horizontal connections 110 to communicate with IC 630 and the vertical connections 110 to communicate with the IC 620. Thus, the 2×3 configuration effectively doubles the amount of chip-to-chip connections 110 that each IC can be have relative to some of the ICs in the 1×2, 1×3, or 1×4 arrangements which communicate using only one side.

In this embodiment, the interposer 600 has a surface area that exceeds a reticle limit of the fabrication techniques used to fabricate the interposer. The size of an IC is limited by the reticle limit which defines the amount of area that can be exposed and processed using masks. Currently, for a monolithic die, the maximum size is limited to 33-26 mm which is the reticle limit. Thus, the widths and heights of the ICs 615, 620, 625, 630, 635, and 640 are limited to this reticle limit.

In order for the interposer 600 to support multiple ICs which have sizes that are at or just below the reticle limit, it has to have a surface area that exceeds the reticle limit. This means that interposer 600 cannot be fabricated using a single exposure process. Instead, the interposer 600 includes a vertical stitch 610 and a horizontal stitch 605 where multiple exposure areas slightly overlap. This permits the interposer to still have traces to form the connections 110 and have sufficient surface area to support the 2×3 configuration of the ICs. In one embodiment, four exposure areas (and four different mask sets) are used to form the vertical and horizontal stitches illustrated in FIG. 6.

In one embodiment, the interposer 600 has a total surface area that is three times the size of the reticle limit (e.g., the maximum reticle field). Moreover, unlike interposers that support 1×2, 1×3, and 1×4 configurations that may only have horizontal stitches, the interposer 600 has both a horizontal stitch 605 and a vertical stitch 610. Moreover, in this example, the horizontal stitch 605 extends through two ICs—IC 620 and IC 635. For example, the ICs 620 and 635 may both include keep-out regions when being designed (e.g., FIG. 4), or the horizontal stitch 605 may align with a boundary between power domains in the two ICs 620 and 635 (e.g., FIG. 5).

Further, in FIG. 6, the vertical stitch 610 does not extend through one of the ICs connected to the interposer 600. Instead, the vertical stitch 610 is aligned between boundaries between the ICs. However, in other implementations the vertical stitch 610 may also extend through ICs. For example, in a 3×3 arrangement, the size of the ICs may be such that a vertical stitch extends through a middle column of ICs in the 3×3 arrangement. In that example, the middle IC in the middle column may be disposed over both the vertical stitch and the horizontal stitch. In that case, one IC may be aligned on the interposer such that both a vertical stitch and a horizontal stitch extend through it.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A device, comprising:
an interposer with a stitch formed from overlapping exposure areas; and
two or more integrated circuits (ICs) disposed on the interposer, wherein a first IC of the two or more ICs is disposed over the stitch, wherein the two or more ICs are connected via the interposer.

2. The device of claim 1, wherein a total surface area of the interposer is greater than a maximum reticle field corresponding to the exposure areas.

3. The device of claim 1, wherein the stitch aligns with a keep-out region in the first IC.

4. The device of claim 3, wherein the keep-out region excludes bumps, copper pillars, or redistribution layers (RDLs).

5. The device of claim 1, wherein the stich aligns with a region in the first IC that does not have power bumps.

6. The device of claim 1, wherein the first IC comprises a first power domain and a second power domain, wherein the stitch is aligned with a boundary between the first and second power domains.

7. The device of claim 6, wherein the first power domain includes a different type of circuitry than the second power domain.

8. The device of claim 1, wherein the stitch is formed by slightly overlapping two exposure areas, wherein both of the two exposure areas is at or below the maximum reticle field.

9. The device of claim 1, wherein the first IC has a different size than a second IC of the two or more ICs.

10. The device of claim 9, wherein a combined length of the first and second ICs exceeds the maximum reticle field.

11. The device of claim 10, wherein the first IC has a different size than a third IC of the two or more ICs, wherein a combined length of the first and third ICs exceeds the maximum reticle field, wherein the first IC is disposed between the second and third ICs on the interposer.

12. A method, comprising:
forming an interposer with stitch using overlapping exposure areas; and
disposing two or more ICs on the interposer, wherein a first IC of the two or more ICs is disposed over the stitch, wherein the two or more ICs are connected via the interposer.

13. The method of claim 12, wherein a total surface area of the interposer is greater than a maximum reticle field corresponding to the exposure areas.

14. The method of claim 12, wherein the stitch aligns with a keep-out region in the first IC.

15. The method of claim 12, wherein the first IC comprises a first power domain and a second power domain, wherein the stitch is aligned with a boundary between the first and second power domains.

16. The method of claim 15, wherein the first power domain includes a different type of circuitry than the second power domain.

17. The method of claim 12, wherein the stitch is formed by slightly overlapping two exposure areas, wherein both of the two exposure areas is at or below the maximum reticle field.

18. The method of claim 12, wherein the first IC has a different size than a second IC of the two or more ICs, wherein a combined length of the first and second ICs exceeds the maximum reticle field.

19. The method of claim 18, wherein the first IC has a different size than a third IC of the two or more ICs, wherein a combined length of the first and third ICs exceeds the maximum reticle field, wherein the first IC is disposed between the second and third ICs on the interposer.

20. A device, comprising:
an interposer with a stitch formed from overlapping exposure areas;
a first IC disposed on the interposer, wherein the first IC is disposed over the stitch; and
a second IC disposed on the interposer and is not disposed over the stitch, wherein the first and second ICs are connected using chip-to-chip connections in the interposer.
